(19) United States
(12) Patent Application Publication
(10) Pub. No.: US 2008/0253079 A1
(43) Pub. Date: Oct. 16, 2008

(54) METHODS AND SYSTEMS OF SELECTING FUNCTIONALITY OF A PORTABLE COMPUTER

(76) Inventors: Ian N. Robinson, Pebble Beach, CA (US); Craig Sayers, Menlo Park, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/734,353

(22) Filed: Apr. 12, 2007

(51) Int. Cl. H05K 5/00

(52) U.S. Cl. 361/686

(57) ABSTRACT

Methods and systems of selecting functionality of a portable computer. At least some of the illustrative embodiments are methods comprising inserting a portable computer into a cradle unit, and implementing a functionality by the portable computer (the functionality selected at least in part by interaction between the portable computer and the cradle unit).

### BACKGROUND

Portable computers, such as personal digital assistants (PDAs) have versatile functionality. For example, PDAs operate as cellular telephones, have calendar programs, execute word processing programs, and in some cases enable the user to search the Internet. Some industries utilize PDAs for industry specific functionality. For example, realtors in some major markets use PDAs as the mechanism to access keys from lock boxes. However, in some cases switching between functionalities, or using the functionality itself, is difficult given the small size and limited input/output (I/O) capabilities implemented on most PDAs.

### BRIEF DESCRIPTION OF THE DRAWINGS

For a detailed description of exemplary embodiments, reference will now be made to the accompanying drawings in which:

FIG. 1 shows an electrical block diagram of a portable computer and a cradle unit for the portable computer;

FIG. 2 shows a perspective view of an embodiment of a portable computer and the cradle unit;

FIG. 3 shows a perspective view of an embodiment of a portable computer and a cradle unit that triggers alarm clock functionality of the portable computer; and

FIG. 4 shows a method in accordance with at least some embodiments.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .”

Also, the term “couple” or “couples” is intended to mean either an indirect, direct, optical or wireless electrical connection. Thus, if a first device couples to a second device, that connection may be through a direct connection or, through an indirect electrical connection via other devices and connections.

### DETAILED DESCRIPTION

The following discussion is directed to various embodiments. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment. The various embodiments were developed in the context of personal digital assistants (PDAs), and thus the description is based on the developmental context; however, the various embodiments are not limited to just PDAs, as the various embodiments are applicable to any portable computer, such as notebook or laptop computers and digital music players.

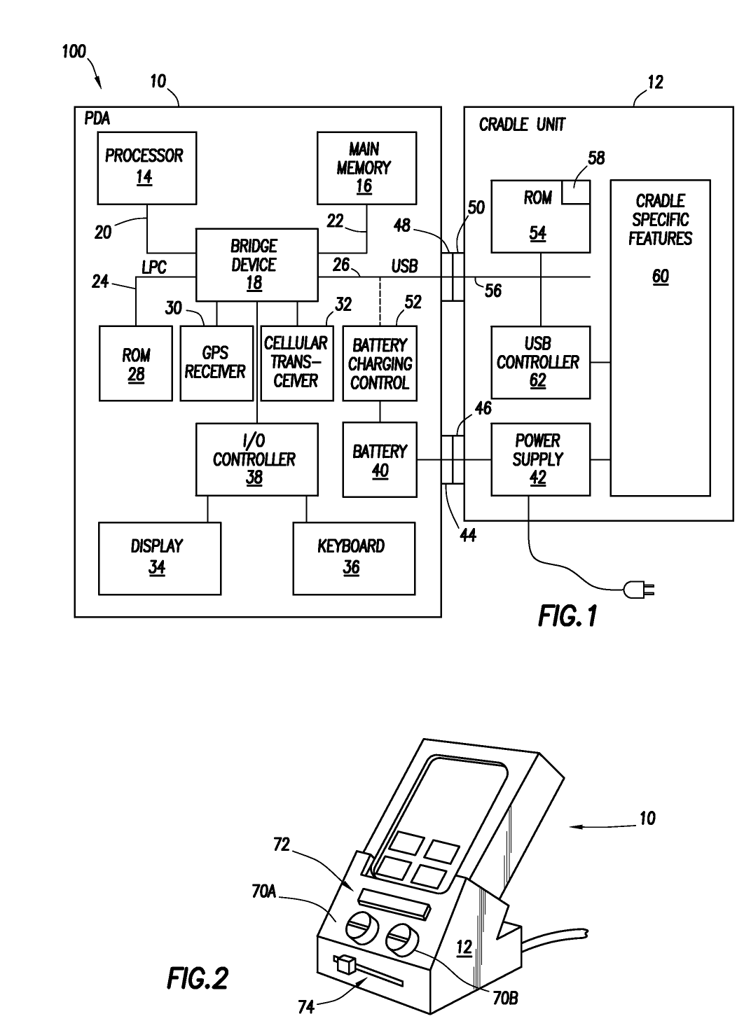

FIG. 1 shows an electrical block diagram of a system 100 in accordance with at least some embodiments. In particular, the system 100 comprises a PDA 10 selectively coupled to a docking station or cradle unit 12. In accordance with the various embodiments, the functionality implemented by the PDA 10 when docked to the cradle unit 12 is selected, at least in part, by the interaction between the PDA 10 and the cradle unit 12. Stated otherwise, docking or undocking the PDA 10 with the cradle unit 12 causes the PDA 10 to implement particular functionality. Before delving into specific mechanisms of the selecting of the functionality, attention turns to illustrative internal configurations of both the PDA 10 and the cradle unit 12.

PDA 10 comprises a processor 14 coupled to a main memory 16 by way of a bridge device 18. In particular the processor 14 couples to the bridge device 18 by way of a processor bus 20, and the main memory 16 couples to the bridge device 18 by way of a memory bus 22. The main memory 16 may be any suitable memory device or array of memory devices in which instructions to be executed by the processor, and data, may be stored. In some embodiments, some or all of the main memory 16 is non-volatile memory, meaning that contents of the memory are not lost during powered-off conditions of the PDA 10. The non-volatility may be inherent in the device or devices that make up the main memory 16 (e.g., flash memory or magnetic random access memory), or the non-volatility may be implemented by providing battery backup to volatile memory devices.

In addition to bridging the processor 14 to the main memory 16, the bridge device 18 also bridges the processor bus 20 and memory bus 22 to various secondary expansion buses, and devices coupled thereto. For example, the PDA 10 may comprise a read only memory (ROM) 28 coupled to the bridge device 18 by way of a low pin count (LPC) bus 24. The ROM 28 stores programs executable by the processor 14 to implement at least some of the various functionalities. Further, the PDA 10 may comprise a GPS receiver 30 coupled to the bridge device 18. The GPS receiver 30 receives signals from orbiting satellites, and based on the received signals the receiver 30, or the processor 14 executing appropriate software, determines the spatial parameters of the PDA 10, such as location, altitude and velocity. The PDA 10 may further comprise a cellular transceiver 32 coupled to the bridge device 18. The cellular transceiver 32 interacts with cellular towers and alone, or in combination with software executed on the processor 14, implements cellular telephone functionality.

In order for a user of the PDA 10 to interact with the PDA and utilize the various functionalities of the PDA, the PDA 10 further comprises input/output (I/O) devices, such as display 34 and keyboard 36. The display 34 is any suitable display, such as a liquid crystal display, on which text and graphics are displayed. The keyboard 36 is any suitable number of keys to enable interfacing to the PDA 10 (e.g., a single pushbutton, a thumbwheel, a touch-screen overlay, a multi-directional rocker switch or a “qwerty” keyboard (even if that keyboard is of reduced size)). The illustrative display 34 and keyboard 36 couple to an I/O controller 38, which in turn couples to the bridge device 18.

Because the PDA 10 is a portable device, the PDA 10 further comprises a battery 40. The battery 40 provides power the various devices in the PDA 10, but the electrical coupling to enable powering the various devices is not shown so as not to unduly complicate the figure. Charging of the battery 40 may take many forms. In some embodiments, the battery 40 is charged based on power provided directly from a power supply 42 in the cradle unit 12 when the PDA is docked to the cradle unit 12. In these embodiments, the PDA 10 comprises a power connector or power port 44, and likewise the cradle unit 12 comprises a mating power connector or power port 46. When the PDA 10 is physically docked to the cradle unit 12, the power connectors 44 and 46 couple such that the power supply 42 charges the battery 40.

In alternative embodiments, power to charge battery 40 may be drawn from other sources of power. For example, in some embodiments the PDA 10 and cradle unit 12 of system 100 communicate by way of a serial communication bus, and in the illustrative case of FIG. 1 by way of USB 26. Under the USB protocol, primary devices (such as cradle unit 12) provide power in the form of a 5 Volt power signal applied to the conductors of the bus. In accordance with at least some embodiments, the PDA 10, in addition to communicating across the illustrative USB 26, uses the power provided from the cradle unit 12 across the USB 26 to charge the battery 40. In particular, the PDA 10 comprises a communication port 48, and likewise the cradle unit 12 comprises a mating communication port 50. When the PDA 10 is physically coupled to the cradle unit 12, the communication ports 48 and 50 couple such data packets flow back and forth between the PDA 10 and the cradle 12. Further, the power provided by the cradle unit 12 under the USB protocol is available within the PDA 10. A battery charging control unit 52 couples to the illustrative USB 26, and draws power from the USB 26 to charge battery 40.

Turning now to the cradle unit 12, cradle unit 12 comprises a read only memory (ROM) 54 (e.g., a serially accessible electrical erasable programmable ROM (Serial EEPROM)) coupled to the USB 56 within the cradle unit 12. Thus, the PDA 10 accesses values stored in the ROM 54, for example value 58. In some embodiments, the power supply 42 and ROM 54 are the only electrically components of the cradle unit 12.

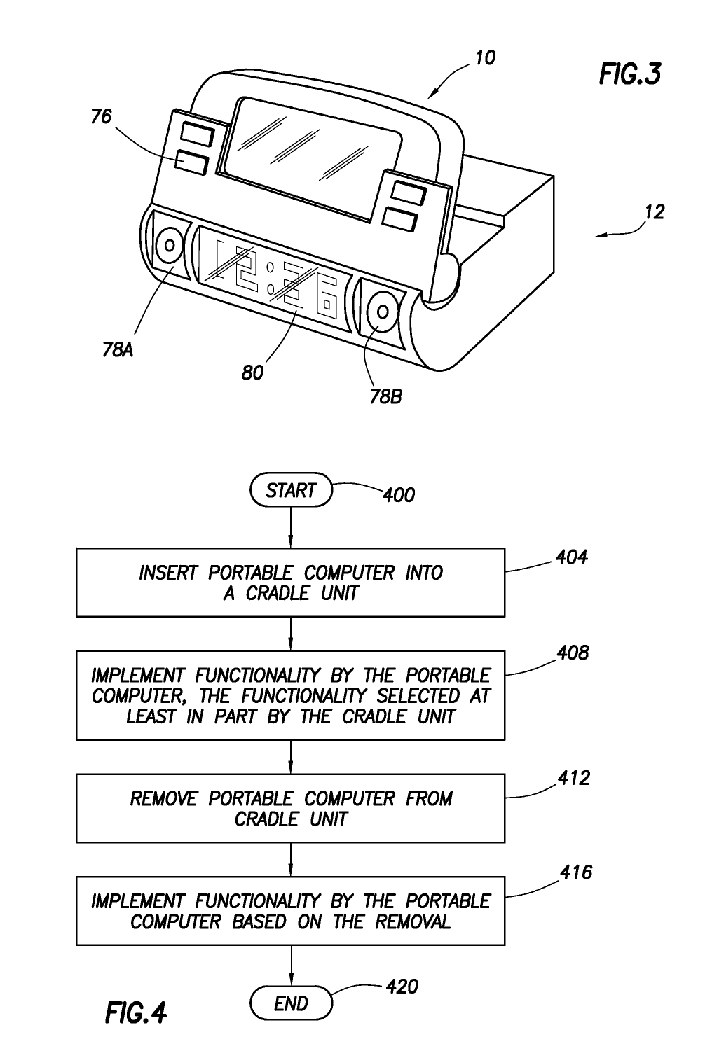

In alternative embodiments, the cradle unit 12 has features that augment the selected functionality implemented by the PDA 10. FIG. 2 illustrates a perspective view of a PDA 10 coupled to a cradle unit 12. The cradle unit 12 has a plurality of features (e.g., I/O devices such as knobs 70, button 72, slide bar 74, infrared red transmitter/receiver, or GPS sensor if the PDA does not implement one), all of which operatively coupled to the PDA 10 and which augment the functionality of the PDA 10. In some embodiments, the features make use of the PDA better from the standpoint of ergonomics. In other embodiments, the features add function to the PDA 10. Other cradle-specific features are discussed with respect to FIG. 3. All possible features are illustrated in FIG. 1 as cradle-specific features 60. In order for the PDA 10 to operatively couple to the cradle-specific features 60, the cradle unit 12 in these alternative embodiments comprises a USB controller 62 coupled to the cradle-specific features, and also coupled to the USB 56.

In accordance with embodiments, specific functionality implemented by the PDA 10 is selected, at least in part, by the cradle unit 12. Stated otherwise, docking the PDA 10 to a particular cradle unit 12 identifies to the PDA 10 that the user wishes to implement specific functionality (i.e., load and execute programs that perform the functionality). Moreover, when the PDA 10 is removed from the cradle unit 12, implementation of the specific functionality may cease and (optionally) another functionality may be triggered.

FIG. 3 shows an illustrative embodiment of a cradle unit 12 in the form of an alarm clock. When PDA 10 is docked to the cradle unit 12 in the form of an alarm clock, the PDA 10 implements alarm clock functionality. For example, setting the alarm time may be accomplished by the user interfacing with the PDA 10 directly, or by use of buttons 76 on the cradle unit 12. In alternative embodiments, the PDA 10 automatically sets alarm time based on calendar appointments stored in the PDA. In embodiments where the PDA has access to a cellular system and/or the Internet, the PDA 10 checks schedules throughout the night, and adjusts the alarm time accordingly. For example, if an airline flight is cancelled, the PDA 10 may automatically change the alarm time to allow the user to sleep in, yet still have time to make the next flight.

Moreover, illustrative controls (e.g., buttons 76) may alter the alarm clock functionality. For example, a control button 76 on the cradle unit 12 being an alarm clock may: turn off the alarm clock functionality implemented by the PDA 10; arm alarm clock functionality, with the time adjustable by way of the buttons; trigger the alarm clock functionality such that an alarm is sounded a predetermined time before each appointment held in the PDA 10; trigger the alarm clock functionality such that an alarm is sounded a set interval prior to the earliest appointment held in the PDA 10; or trigger an alarm being the earliest of the set time, each appointment or the earliest appointment. Much like the case of airline flight schedules, a PDA 10 with access to a cellular system or the Internet may adjust appointment times, and thus alarm times, based on changes to appointments detected over the cellular or Internet connection.

Still referring to FIG. 3, the illustrative cradle unit 12 has features to assist in the functionality. The features comprise not only buttons 76, but also speakers 78 and display device 80, all of which operatively couple to the PDA 10. The contents of the display device 80, here the time, are selected at least in part by the PDA 10. Moreover, the sounds and/or songs that play over the speakers are selected, at least in part, by the PDA 10. A smaller, simpler version of the alarm clock cradle as shown in FIG. 3 is particularly helpful to travelers. While most hotel and motel rooms have alarm clocks, the interface and operability of the alarm clocks varies widely. A user who travels with regularity may thus take along the cradle unit 12 for alarm clock functionality and for charging of the PDA. Setting the alarm time is accomplished through a consistent interface (i.e., the PDA 10 and specific features 60 of the cradle unit 12), and charging of the PDA 10 may be accomplished by way of the cradle unit 12. Alternatively, alarm time settings may be carried over from previous settings, thus freeing the user from having to set alarm times.

Implementing alarm clock functionality when a PDA 10 is docked to a cradle unit 10 is merely illustrative. The following is a non-limiting discussion of functionality that may be triggered by docking a PDA 10 with a cradle unit 10. With a cradle unit associated with an automobile, docking the PDA 10 in the cradle unit 12 may implement GPS navigation functionality. Yet another cradle unit 12 may trigger telephone functionality, such as functionality to have the PDA 10 act as a speaker-phone for conference calls. Yet another cradle unit may trigger GPS-based pedometer functionality. A cradle unit 12 associated with the home may enable universal audio/visual remote capabilities of the PDA 10. Cradle units 12 with speakers may trigger digital music player functionality of the PDA 10. Information Technology (IT) professionals may have a cradle unit 12 that triggers functionality to assist in installation and trouble-shooting of packet-based message networks (e.g., signal-to-noise ratio line test and throughput testing of Ethernet networks). Electronics technicians may have a cradle unit 12 that triggers functionality to assist in electronic troubleshooting (e.g., multi-meter functionality, digital oscilloscope functionality). Any or all of these cradle units, including the cradle unit that triggers alarm clock functionality, may also charge the battery 40 of the PDA 10, either by power supplied on the communication bus, or by independent power lines between the PDA 10 and cradle unit 12.

Real estate services provide yet another non-limiting set of functionalities selected, at least in part, by docking the PDA 10 to the cradle unit 12. For example, real estate agents might each have two cradle units: one fixed for use at the office; and one in the car. Placing the PDA in the office cradle unit triggers functionality to download any newly-acquired information from the PDA and upload the latest property listings from the real estate agent's company. Placing the PDA 10 in the cradle unit in the car, the PDA switches to a navigation mode using GPS. Removing the PDA from the cradle unit in the car while the car is running switches the PDA to phone functionality. Removing the PDA from the cradle unit in the car while parked near a property listing switches the PDA to an application to display and capture information about that property. Placing the PDA back in the cradle unit in the car associates new data with the current location, such as pictures taken with the PDA. The cradle unit could be further customized with buttons such as: “remember this location,”; “see if this property is listed yet”; “this has been sold”; “ring PDA only if the call is from a number in my contacts list”; or “list properties for sale in this neighborhood.”

Returning to FIG. 1, selecting or triggering the functionality of the PDA 10 by the cradle unit 12 may take many forms. In some embodiments, the ROM 54 of the cradle unit 12 stores the value 58. Upon docking to the cradle unit 12, the PDA 10 reads the value 58, and then the PDA 10 loads and executes programs identified, at least in part, by the value 58. In alternative embodiments, the program that implements the functionality may be running, but only minimally active, and the value identifies the program and makes the program fully active in the PDA 10. The value 58 may thus identify one or more programs to execute, or the value 58 may identify the type of cradle unit 12, and the PDA 10 selects one or more appropriate programs to execute to implement functionality associated with the cradle unit. The programs may be stored in the main memory 16, the ROM 28, or may be downloaded by way of a wireless connection through cellular transceiver 32. In yet still other embodiments, at least a portion of the program executed on the PDA 10 to implement the specific functionality is stored in the ROM 54. Thus, when docked to the cradle unit 12 the PDA 10 reads at least a portion of the program from the cradle unit, and then executes the program to implement the specific functionality.

FIG. 4 illustrates a method in accordance with at least some embodiments. In particular, the method starts (block 400) and proceeds to inserting a portable computer (such as a PDA) into a cradle unit (block 404). The cradle unit may take many forms. In some cases the cradle unit may hold the portable computer in a particular orientation or in a particular location (e.g., a car, or arm of jogger) while triggering particular functionality, and in other embodiments the cradle unit may assist in the functionality by implementing various function specific features (e.g., buttons, knobs, slide bars, speaker or display devices). Thereafter, the portable computer implements functionality selected at least in part by the cradle unit (block 408). Implementing the functionality may take many forms. In some embodiments the cradle unit stores a value. The value is read by the portable computer, and the software executed to implement the functionality is selected based on the value. In some embodiments the software for the functionality is already executing in a minimal form, but is identified and made fully active based on the value. In yet still other embodiments, the cradle unit stores some or all of the software executed to implement the functionality. In these alternative embodiments, the portable computer reads the software from the cradle unit, and then executes the software to implement the functionality.

At some point thereafter, the portable computer is removed from the cradle unit (block 412). In some embodiments, removing the portable computer from the cradle unit itself implements functionality (block 420), and the method ends (block 420). For example, when the portable computer is docked to a cradle unit in a car, the portable computer may implement GPS functionality. When removed from the cradle unit in the car, the portable computer may stop programs associated with the GPS functionality, and may revert to another functionality, such as cellular telephone functionality. Changing from GPS functionality to telephone functionality by the PDA 10 responsive to removal of the PDA 10 from the cradle is merely illustrative, and it should be appreciated that other functionality changes responsive to removal are also possible.

What is claimed is:

1. A method comprising:
inserting a portable computer into a cradle unit; and
implementing a functionality by the portable computer, the functionality selected at least in part by interaction between the portable computer and the cradle unit.

2. The method as defined in claim 1 wherein implementing further comprises:
reading a value from the cradle unit by the portable computer; and
executing a software program selected based on the value.

3. The method as defined in claim 1 where implementing further comprises:
reading a value by one or more selected from the group consisting of:
reading the value from an electrically erasable programmable read only memory (EEPROM) device in the cradle unit; reading the value from the cradle unit across a serial communication bus; or reading the value from the cradle unit across a Universal Serial Bus (USB); and
executing a software program selected based on the value.

4. The method as defined in claim 1 wherein implementing further comprises:
transferring a computer program from the cradle unit to the portable computer; and
executing the computer program by the portable computer to implement the functionality.

5. The method as defined in claim 1 wherein implementing further comprises implementing one or more functionalities selected from the group consisting of: an alarm clock; a GPS-based navigation device; a packet-based communication diagnostic device; an electronics troubleshooting device; a wireless telephone; a GPS-based pedometer; an audio/visual remote control; or a digital format music player.

6. The method as defined in claim 1 further comprising employing at least one feature of the cradle unit to augment the functionality.

7. The method as defined in claim 6 wherein employing further comprises implementing one or more functionalities selected from the group consisting of: a button on the cradle unit operatively coupled to the portable computer; a knob on the cradle unit operatively coupled to the portable computer; a display device on the cradle unit operatively coupled to the portable computer, the contents of the display device at least partially selected by the portable computer; or a speaker of the cradle unit operatively coupled to the portable computer, the sounds produced by the speaker at least partially selected by the portable computer.

8. The method as defined in claim 1 wherein inserting further comprises inserting the portable computer being a personal digital assistant (PDA) into the cradle unit.

9. The method as defined in claim 1 further comprising:
removing the portable computer from the cradle unit; and
implementing a functionality by the portable computer responsive to the removal from the cradle unit.

10. A system comprising:
a cradle unit comprising:
a communication port; and
a memory coupled to the communication port, the memory storing a value;
a portable computer coupled to the cradle unit, the portable computer having a communication port that couples to the communication port of the cradle unit;
wherein the portable computer executes a program determined at least in part by the value in the cradle unit.

11. The system as defined in claim 10 wherein the portable computer reads the value stored in the memory over the communication port, and wherein the portable computer selects the program to execute based on the value.

12. The system as defined in claim 10 wherein the memory of the cradle unit stores the program, and wherein the portable computer reads at least a portion of the program from the memory device and then executes the program.

13. The system as defined in claim 10 wherein the cradle unit further comprises an Input/Output (I/O) device, and wherein the I/O device enables a user to interact with the program.

14. The system as defined in claim 10 wherein the cradle unit further comprises an Input/Output (I/O) device that enables a user to interact with the program, the I/O device one or more selected from the group consisting of: a push-button; a knob; a display device, the contents of the display device at least partially selected by the portable computer; or a speaker, the sounds produced by the speaker at least partially selected by the portable computer.

15. The system as defined in claim 10 wherein, when docked, the portable computer executes the program to implement functionality being one or more selected from the group consisting of: an alarm clock; a GPS based navigation device; a packet-based communication diagnostic device; an electronics troubleshooting device; a wireless telephone; a GPS-based pedometer; an audio/visual remote control; or a digital format music player.

16. The system as defined in claim 10 wherein the cradle unit further comprises a power connection that couples to a source of power, and wherein the cradle unit provides power to the portable computer.

17. The system as defined in claim 10 wherein the cradle unit provides power to the portable computer over the communication port.

18. The system as defined in claim 10 further comprising:
said cradle unit comprising a power port; and
said portable computer comprising a power port that couples to the power port of the cradle unit;
wherein the cradle unit provides power to the portable computer over the power port.

19. A system comprising:
a means for portable execution of programs;
a means for receiving the means for portable execution in a cradle;
wherein the means for portable execution executes a program selected at least in part by the means for receiving.

20. The system as defined in claim 19 wherein the means for portable execution reads a value stored in a means for storing programs and data within the means for receiving, the reading over a means for communication, and wherein the means for execution selects the program to execute based on the value.

21. The system as defined in claim 20 wherein the means for storing stores the program, and wherein the means for portable execution reads at least a portion of the program from the means for storing and then executes the program.

22. The system as defined in claim 19 wherein the cradle unit further comprises a means for Input/Output (I/O), and wherein the means for I/O enables a user to interact with the program.

23. The system as defined in claim 19 wherein the means for receiving further comprises a means for charging the means for portable execution when the means for portable execution is docked in the means for receiving.
